(19) United States
(12) Patent Application Publication
(10) Pub. No.: US 2025/0101182 A1
(43) Pub. Date: Mar. 27, 2025

(54) POLY(ESTER-IMIDE) POLYMERS AND USES THEREOF

(71) Applicant: SOLVAY SPECIALTY POLYMERS USA, LLC, Alpharetta, GA (US)

(72) Inventors: Chad Powell, Alpharetta, GA (US); Ryan Mondschein, Cumming, GA (US); Stéphane Jeol, Saint-Genis-Laval (FR); Joel Pollino, Johns Creek, GA (US)

(73) Assignee: SOLVAY SPECIALTY POLYMERS USA, LLC, Alpharetta, GA (US)

(21) Appl. No.: 18/727,218

(22) PCT Filed: Jan. 6, 2023
(86) PCT No.: PCT/EP2023/050231

§ 371 Date: Jul. 8, 2024

(30) Foreign Application Priority Data
Jan. 6, 2022 (EP) 22305008.9

(51) Int. Cl. C08G 73/16; C08J 5/12; H05K 1/03

(52) U.S. Cl. CPC C08G 73/16; C08J 5/12; C08J 2379/08; H05K 1/0373

(57) ABSTRACT

The present disclosure relates to poly(ester-imide)s (“PEIs”) exhibiting low dielectric constant and dissipation factors, and uses thereof. Such polymers can be used for producing articles, such articles being suitable for mobile electronic device components, for example films or structural components. The present disclosure further relates to solutions comprising the PEIs and use of the solutions for the manufacture of films or mobile electronic device articles or components.

### CROSS REFERENCE TO RELATED APPLICATIONS

This application claims priority to European patent application No. 22305008.9 filed on Jan. 6, 2022, the whole content of this application being incorporated herein by reference for all purposes.

### FIELD OF THE DISCLOSURE

The present disclosure relates to poly(ester-imide)s (“PEIs”) exhibiting low dielectric constant and dissipation factors, and uses thereof. Such polymers can be used for producing articles, such articles being suitable for mobile electronic device components, for example films or structural components. The present disclosure further relates to solutions comprising the PEIs and use of said solutions for the manufacture of films or mobile electronic device articles or components.

### BACKGROUND OF THE DISCLOSURE

Due to their reduced weight and high mechanical performance, polymer compositions are widely used to manufacture mobile electronic device components. To meet the growing demand for device hyperconnectivity, electronic components have become increasingly intricate. This increase in device connectivity will be facilitated primarily by an increase in data transfer rates and network capacity enabled by 5G cellular networks. To meet the demands of 5G networks, operating at frequencies up to 100 GHz, dielectric insulating materials must demonstrate low dielectric constants (Dk) and dissipation factors (Df), typically below 4.0 and 0.0035, respectively.

JP 2009/286683 (Asahi Kasei Materials Corp) (D1) and JP H01 185324 (Idemitsu Kosan Co) (D2) do not disclose polymers containing the recurring units (I).

The dielectric constant represents the ability of the material to interact with the electromagnetic radiation and disrupt electromagnetic signals (e.g. radio signals) travelling through the material. Accordingly, the lower the dielectric constant of a material at a given frequency, the less the material disrupts the electromagnetic signal at that frequency. Dissipation factor is the reciprocal of the ratio between a material's capacitive reactance to its resistance at a specified frequency. It measures the electromagnetic energy absorbed and lost (power dissipation) when electromagnetic radiation is applied. The lower the dissipation factor (Df), the less the material absorbs electromagnetic radiation and dissipates it, typically as heat.

The current material standard for dielectric insulator substrates in printed circuit boards (“PCBs”) and flexible printed circuits (“FPCs”) is polyimide (PI), which is traditionally prepared in solution form as a polymer precursor, cast into film form, and heat treated to form the final PI film substrate. However, PIs suffer from high moisture uptake due, at least in part, to an imide moiety being present in each repeat unit. The process of moisture uptake causes a concomitant increase in Df. In less demanding dielectric applications this increase in Df was tolerable as it did not affect the performance in the frequency ranges utilized for previous generations of cellular networks (e.g., 4G LTE). However, in the more demanding 5G electronics space, this performance deterioration with moisture uptake causes enhanced signal dampening at higher frequencies. Thus, it is desirable to prepare alternatives to PI with the appropriate dielectric performance, that can be cast from solution using a widely-available solvent, with improved dielectric performance under both dry and humid conditions.

Accordingly, there is an ongoing need for the development of compositions and materials that are easier to process into films or mobile electronic device articles or components while also exhibiting desirable dielectric performance, i.e., low dielectric constant and dissipation factor, in both high and low humidity environments.

It has been discovered that the polymers of the invention can easily be processed into mobile electronic device articles or components, such as films, while also exhibiting desirable dielectric performance, such as low dielectric constant and/or dissipation factor, in both high and low humidity environments.

### SUMMARY OF THE DISCLOSURE

The invention is set out in the appended set of claims. The invention relates to a polymer as defined in any one of claims 1-34. The invention also relates to a polymer composition as defined in any one of claims 35-39. The invention also relates to a mobile device article or component as defined in any one of claims 40-43. The invention further relates to a solution as defined in any one of claims 42-44. The invention further relates to a use of the solution as defined in any one of claims 47-49 for the manufacture of a film, or of a mobile electronic device article or component, or of of an automotive, aeronautics or drone article or component, or of a metal clad laminate. The invention yet further relates to a metal clad laminate as defined in any one of claims 50-51.

More precisions and details about these subject-matters are now provided below.

### Definitions

As used herein, the terms “a”, “an”, or “the” means “one or more” or “at least one” and may be used interchangeably, unless otherwise stated. As used herein, the term “and/or” used in a phrase in the form of “A and/or B” means A alone, B alone, or A and B together.

As used herein, the term “comprises” is synonymous with “including,” “containing,” or “characterized by,” is intended to be inclusive or open-ended and does not exclude additional, unrecited elements or steps. The term “consisting essentially of” is inclusive of the specified materials or steps and those that do not materially affect the basic characteristic or function of the composition, process, method, or article of manufacture described. The term “consisting of” excludes any element, step, or component not specified.

Unless defined otherwise, all technical and scientific terms used herein have the same meaning as is commonly understood by one of skill in the art to which this specification pertains.

The term “arylene” as used herein refers to a divalent unsaturated hydrocarbon radical containing one or more six-membered carbon rings in which the unsaturation may be represented by three conjugated double bonds. Arylene radicals include monocyclic arylenes and polycyclic arylenes.

“Polycyclic arylene” refers to a divalent unsaturated hydrocarbon radical containing more than one six-membered carbon ring in which the unsaturation may be represented by three conjugated double bonds wherein adjacent rings may be linked to each other by one or more bonds, divalent bridging groups, such as sulfoxides (—SO—), sulfones (—SO₂—), ethers (—O—), carbonyls (—CO—), thioethers (—S—), alkylenes, alkenylenes, and the like, or may be fused together. Arylene radicals may be substituted at one or more carbons of the ring or rings with hydroxyl, cyano, alkyl, alkoxyl, alkenyl, halo, haloalkyl, monocyclic aryl, amino, —(C═O)-alkyl, —(C═O)O-alkyl, —(C═O)-haloalkyl, or —(C═O)-(monocyclic aryl). Examples of arylene radicals include, but are not limited to, phenyl, styrylbenzene phenyl, (phenylsulfonyl)phenyl, phenoxyphenyl, phenylalkylphenyl, phenylcarbonylphenyl, biphenyl, triphenyl, anthracenyl, naphthyl, phenanthrenyl, and the like. The term and phrases “invention,” “present invention,” “instant invention,” and similar terms and phrases as used herein are non-limiting and are not intended to limit the present subject matter to any single embodiment, but rather encompasses all possible embodiments as described.

The proportions of recurring units in the polymer are given in mol % relative to the total amount of moles of recurring units in the polymer.

### DETAILED DESCRIPTION

### Polymer

In a first aspect, the present disclosure relates to a polymer comprising:
at least 30 mol % of recurring units of formula (I) or of a combination of recurring units of formula (I) and recurring units selected from the group consisting of recurring units of formula (II), (III) and combination thereof:

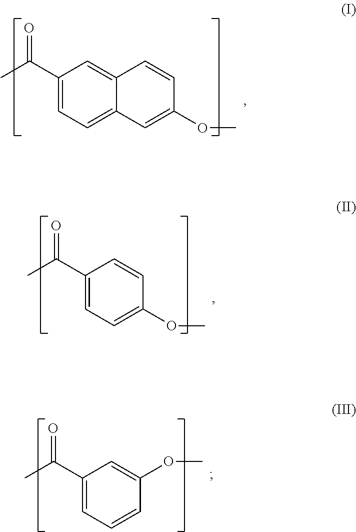

from 1 mol % to 35 mol % of recurring units of formula (IV):

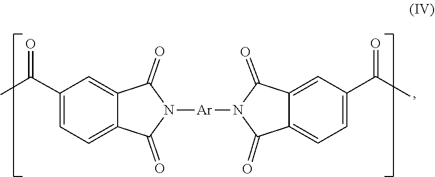

wherein Ar is selected from the group consisting of:

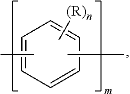

wherein:
each occurrence of R is a C₃-C₈ spiro-substituted cycloaliphatic group, —NO₂, —CN, —OH or a haloalkyl group,
m is an integer from 1 to 3, and
each occurrence of n is an integer from 0 to 4, with the proviso that at least one occurrence of n is an integer from 1 to 4;

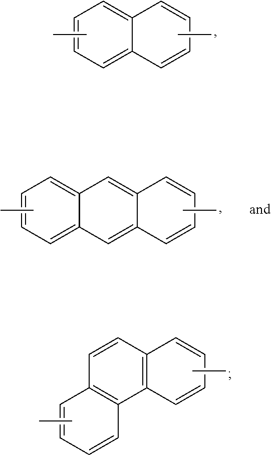

and
from 10 mol % to 35 mol % of recurring units of formula (V):

[—O—Ar₁—O—] (V)
wherein Ar₁ is a C₆-C₁₈ arylene or —Ar_{c}-L₂-Ar_{d}—,
wherein Ar_{c} and Ar_{d} are each, independently, C₆-C₁₈ arylene, and L₂ is a divalent group selected from the group consisting of a bond, —O—, —S—, —SO—, SO₂—, —(C═O)—, —(C═O)O—, —(C═O)NH—, —(C═S)S—, —CH═CH—, —C(CH₃)₂—, and —C(CF₃)₂—, said mol % being relative to the total amount of moles of recurring units in the polymer.

The polymer of the invention can be described as a “poly(ester-imide)” since its backbone is formed of units linked together by imide (present in recurring units (IV)) and ester groups. Thus, the recurring units (I), (II) (if any), (III) (if any), (IV), (V), (VI) (if any) and (VII) (if any) are linked together by ester groups.

### Recurring Units (I)/Combination of Recurring Units (I) and Other Recurring Units (II), (III)

The polymer comprises at least 30 mol % of recurring units of formula (I) or a combination of recurring units of formula (I) and recurring units selected from the group consisting of recurring units of formula (II), (III) and combination thereof. For instance, the polymer may comprise at least 30 mol % of a combination of recurring units (I) and (II), or of a combination of recurring units (I) and (III) or of a combination of recurring units (I), (II) and (III).

The total proportion of recurring units of formula (I) or of the combination of recurring units of formulae (I) with recurring units (II) and/or (III) in the polymer is at least 30 mol %, typically from 30 mol % to 99 mol %, preferably from 30 mol % to 89 mol %, more preferably from 50 mol % to 85 mol % or from 60 mol % to 85 mol %, yet more preferably from 60 mol % to 70 mol %, said mol % being relative to the total amount of moles of recurring units in the polymer.

This proportion may be preferably from 30 mol % to 99 mol %, more preferably from 30 mol % to 89 mol %, yet more preferably from 30 mol % to 80 mol. %, even more preferably from 50 mol % to 80 mol % or from 55 to 75 mol % or from 60 mol % to 70 mol %. This proportion may also advantageously be from 58 to 72 mol %.

This proportion may also be preferably from 30.0 mol % to 99.0 mol %, more preferably from 30.0 mol % to 89.0 mol %, yet more preferably from 30.0 mol % to 80.0 mol. %, even more preferably from 50.0 mol % to 80.0 mol % or from 55.0 to 75.0 mol % or from 60.0 mol % to 70.0 mol %. This proportion may also advantageously be from 58.0 to 72.0 mol %.

When recurring units (I) are combined with recurring units (II) and/or (III), the proportion of recurring units (I) is preferably at least 5 mol %, preferably at least 10 mol %, preferably at least 20 mol %, preferably at least 40 mol %, preferably at least 50 mol %.

### Recurring Units of Formula (IV)

The polymer comprises from 1 mol % to 35 mol % of recurring units of formula (IV), relative to the total amount of moles of recurring units in the polymer. This proportion may preferably be from 5 to 35 mol % or from 10 to 25 mol %. This proportion may also advantageously be from 15 to 22 mol %.

This proportion may also preferably be from 5.0 to 35.0 mol % or from 10.0 to 25.0 mol %. This proportion may also advantageously be from 15.0 to 22.0 mol %.

Recurring units are of formula (IV):

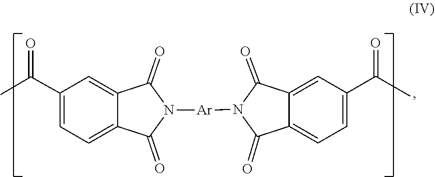

wherein Ar is selected from the group consisting of:

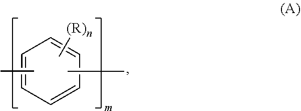

wherein
   each occurrence of R in formula (A) is a C₃-C₈ spiro-substituted cycloaliphatic group, —NO₂, —CN, —OH, or a haloalkyl group,
   m is an integer from 1 to 3, and
   each occurrence of n is an integer from 0 to 4, with the proviso that at least one occurrence of n is an integer from 1 to 4;

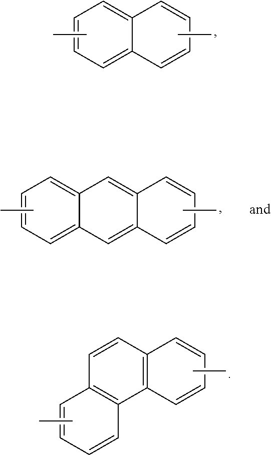

Ar may more particularly be represented by the following formula (A):

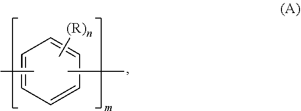

wherein
   each occurrence of R in formula (A) is a C₃-C₈ spiro-substituted cycloaliphatic group, —NO₂, —CN, —OH or a haloalkyl group,
   m is an integer from 1 to 3, and
   each occurrence of n is an integer from 0 to 4, with the proviso that at least one occurrence of n is an integer from 1 to 4.

m may be 1 or 2 or 3.

The proviso is intended to mean that at least one of the arylene group in formula (A) is substituted by at least one R. For example, when m=1, the sole arylene group in formula (A) is a phenyl substituted with (R)ₙ with n is from 1 to 4; when m=2 or 3, at least one of the arylene groups in formula (A) is a phenyl substituted with (R)ₙ with n being from 1 to 4.

According to an embodiment, for m=2 or 3, all arylene groups in formula (A) are phenyl substituted with (R)ₙ with n being from 1 to 4.

n may more particularly be 1.

Unless otherwise indicated, the bonds that are not connected to a specific carbon in the aromatic groups described herein are not limited as to their position on the aromatic rings. According to an embodiment, in formula (A), the bonds are in para position.

Ar is preferably represented by the following formula (A1):

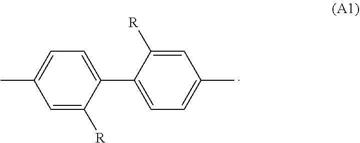

Each occurrence of R in formulae (A) or (A1) may be selected in the group consisting of a C₃-C₈ spiro-substituted cycloaliphatic group, —NO₂, —CN, —OH and —(CHₚX_{q})ᵣCHₚX_{q′}, wherein each occurrence of X is a halogen atom (typically F, Cl, Br, or I, more typically F or Cl), p and q are each an integer from 0 to 2, p′ and q′ are each an integer from 0 to 3, r is an integer from 0 to 20, satisfying the conditions that p+q=2, p′+q′=3 and q+q′ are equal to or greater than 1.

Each occurrence of R in formulae (A) or (A1) may more particularly be selected in the group consisting of a C₃-C₈ spiro-substituted cycloaliphatic group, —NO₂, —CN, —OH and —CX₃, wherein each occurrence of X is a halogen atom (typically F, Cl, Br, or I, more typically F or Cl).

R may be more particularly —CX₃ wherein X is a halogen atom.

The recurring units of formula (IV) are preferably of formula (IVa):

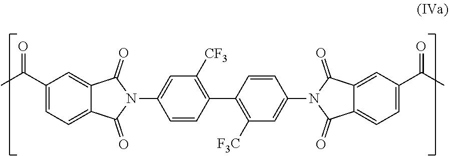

### Recurring Units (V)

The polymer also comprises from 10 to 35 mol. % of recurring units of formula (V):

[—O—Ar₁—O—] (V)
wherein Ar₁ is a C₆-C₁₈ arylene or —Ar_{c}-L₂-Ar_{d}—, wherein Ar_{c} and Ar_{d} are each, independently, C₆-C₁₈ arylene, and L₂ is a divalent group selected from the group consisting of a bond, —O—, —S—, —SO—, SO₂—, —(C═O)—, —(C═O)O—, —(C═O)NH—, —(C═S)S—, —CH═CH—, —C(CH₃)₂—, and —C(CF₃)₂—, this proportion being relative to the total amount of moles of recurring units in the polymer.

This proportion may preferably be from 10 to 25 mol %. This proportion may also advantageously be from 15 to 22 mol % or from 10 to 20 mol %.

This proportion may also preferably be from 10.0 to 25.0 mol %. This proportion may also advantageously be from 15.0 to 22.0 mol % or from 10.0 to 20.0 mol %.

According to an embodiment, Ar₁ is selected from the group consisting of:

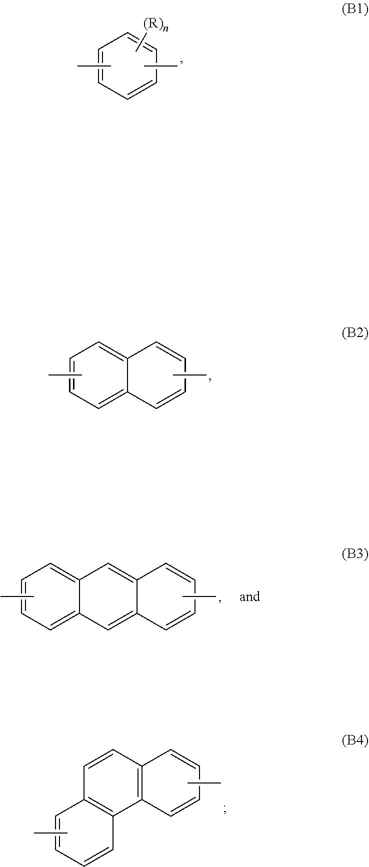

wherein each occurrence of R in formula (I) is H, alkyl, typically C₂-C₈ alkyl; aryl, typically phenyl; cycloaliphatic, typically C₃-C₈ spiro-substituted cycloaliphatic; halogen, typically F, Cl, Br, or I; —NO₂, —CN, —CX₃, wherein X is a halogen, typically F, Cl, Br, or I; or —ORₐ, wherein Rₐ is H, alkyl, typically C₂-C₈ alkyl, more typically methyl or ethyl; and n is an integer from 0 to 4.

Preferably, n is 0.

According to a preferred embodiment, Ar₁ is represented by the following formula:

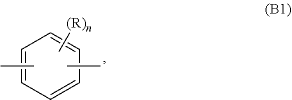

wherein each occurrence of R in formula (B1) is H, alkyl, typically C₂-C₈ alkyl; aryl, typically phenyl; cycloaliphatic, typically C₃-C₈ spiro-substituted cycloaliphatic; halogen, typically F, Cl, Br, or I; —NO₂, —CN, —CX₃, wherein X is a halogen, typically F, Cl, Br, or I; or —ORₐ, wherein Rₐ is H, alkyl, typically C₂-C₈alkyl, more typically methyl or ethyl; and n is an integer from 0 to 4. Preferably, n is0.

According to another embodiment, Ar₁ is represented by —Ar_{c}-L₂-Ar_{d}—, wherein:
Ar_{c} and Ar_{d} are each, independently, selected from the group consisting of:

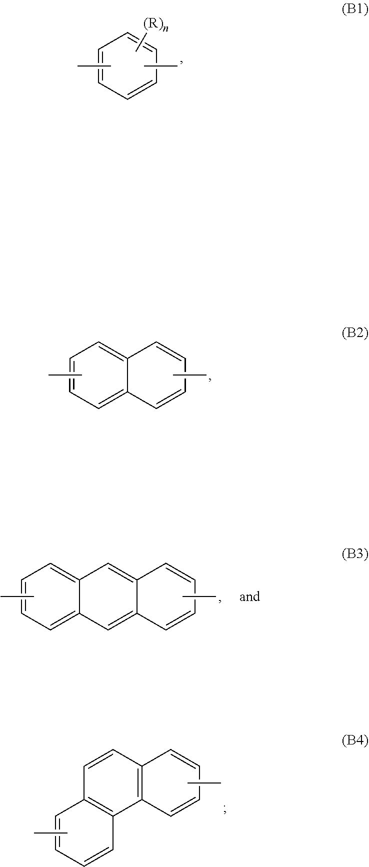

wherein each occurrence of R in formula (B1) is H, alkyl, typically C₂-C₈ alkyl; aryl, typically phenyl; cycloaliphatic, typically C₃-C₈ spiro-substituted cycloaliphatic; halogen, typically F, C, Br, or I, more typically F or Cl; —NO₂, —CN, —CX₃, wherein X is a halogen, typically F, C, Br, or I; or —ORₐ, wherein Rₐ is H, alkyl, typically C₂-C₈ alkyl, more typically methyl or ethyl; and n is an integer from 0 to 4; and
L₂ is a divalent group selected from the group consisting of a bond, —O—, —S—, SO₂—, —(C═O)—, and —C(CF₃)₂—.

According to the embodiment in which Ar₁ in the recurring unit of formula (V) is represented by —Ar_{c}-L₂-Ar_{d}—, L₂ is preferably a bond, and Ar_{c} and Ar_{d} are preferably each represented by:

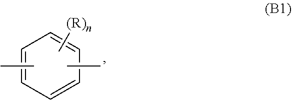

wherein each occurrence of R in formula (B1) is H, alkyl, typically C₂-C₈ alkyl; aryl, typically phenyl; cycloaliphatic, typically C₃-C₈ spiro-substituted cycloaliphatic; halogen, typically F, Cl, Br, or I, more typically F or Cl; —NO₂, —CN, —CX₃, wherein X is a halogen, typically F, Cl, Br, or I; or —ORₐ, wherein Rₐ is H, alkyl, typically C₂-C₈ alkyl, more typically methyl or ethyl; and n is an integer from 0 to 4. Preferably, n is 0.

According to another preferred embodiment, Ar₁ is selected in the group consisting of:

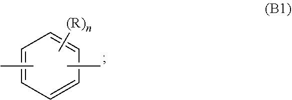

—Ar_{c}-L₂-Ar_{d}— and combination of (B1) and —Ar_{c}-L₂-Ar_{d}—, where L₂ is preferably a bond and Ar_{c} and Ar_{d} are preferably each represented by:

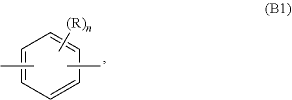

wherein each occurrence of R in formula (B1) is H, alkyl, typically C₂-C₈ alkyl; aryl, typically phenyl; cycloaliphatic, typically C₃-C₈ spiro-substituted cycloaliphatic; halogen, typically F, C, Br, or I, more typically F or Cl; —NO₂, —CN, —CX₃, wherein X is a halogen, typically F, C, Br, or I; or —ORₐ, wherein Rₐ is H, alkyl, typically C₂-C₈ alkyl, more typically methyl or ethyl; and n is an integer from 0 to 4. Preferably, n is 0.

The recurring units of formula (V) are more particularly derived from the following diols: hydroquinone, resorcinol, 4,4′-biphenol, 3,3′-biphenol, 2,4′-biphenol, 2,3′-biphenol, 3,4′-biphenol, isomers of dihydroxynaphthalene, such as 1,4-dihydroxynaphthalene, 1,5-dihydroxynaphthalene, 2,3-dihydroxynaphthalene, 2,7-dihydroxynaphthalene, and 2,6-dihydroxynaphthalene; isomers of dihydroxyanthracene, such as 2,6-dihydroxyanthracene and 9,10-dihydroxyanthracene; and isomers of dihydroxyphenanthrene, such as 9,10-dihydroxyanthracene and 1,9-dihydroxyanthracene. More particularly, the recurring units of formula (V) are derived from the following diols: hydroquinone, resorcinol, 4,4′-biphenol, 3,3′-biphenol, 2,4′-biphenol, 2,3′-biphenol and 3,4′-biphenol. The recurring units of formula (V) are preferably of formula (Va) and/or of formula (Vb):

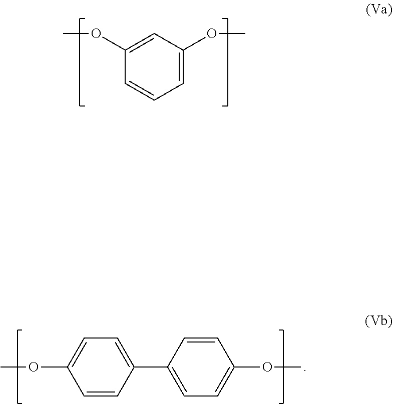

The recurring units of formula (V) may all be of formula (Va). The recurring units of formula (V) may also all be of formula (Vb). The recurring units of formula (V) may all be of a combination of recurring units of formula (Va) and (Vb).

### Recurring Units (VI)

The polymer may further comprise recurring units of formula (VI), [—OC—Ar₂—CO—], wherein Ar₂ is a C₆-C₁₈ arylene group.

When recurring units of formula (VI) are present in the polymer according to the invention, their proportion may be from 0 mol % to 40 mol %, typically from 1 mol % to 35 mol %, said mol % being relative to the total amount of moles of recurring units in the polymer.

### Recurring Units (VII)

The polymer of the present disclosure may further comprise recurring units of formula (VII), [—O—Ar₃—CO—], wherein Ar₃ is a C₆-C₁₈ arylene group, said recurring units of formula (VII) being different from recurring units of formulas (I), (II), and (III).

When recurring units of formula (VII) are present in the polymer according to the invention, their proportion may be from 0 mol % to 30 mol %, typically 1 mol % to 30 mol %, said mol % being relative to the total amount of moles of recurring units in the polymer.

According to a preferred embodiment (E1), the recurring units of the polymer consist essentially of or consist of recurring units of formula (I), recurring units of formula (IV), recurring units of formula (V), and optionally recurring units of formula (II) and/or (III). Pursuant to this embodiment (E1), the recurring units of formula (V) are more particularly recurring units of formula (Va) and/or (Vb).

According to a preferred embodiment (E2), notably applicable to embodiment (E1), the proportions of recurring units in the polymer are the following ones:
recurring units (I) or combination of recurring units (I) and recurring units (II) and/or (III): from 55 to 75 mol %, preferably from 58 to 72 mol %, preferably from 60 to 70 mol %;
recurring units (IV): from 10 to 25 mol %, preferably from 15 to 22 mol %;
recurring units (V): from 10 to 25 mol %, preferably from 15 to 22 mol %.

Pursuant to this embodiment (E2), these proportions may also be the following ones:
recurring units (I) or combination of recurring units (I) and recurring units (II) and/or (III): from 55.0 to 75.0 mol %, preferably from 58.0 to 72.0 mol %, preferably from 60.0 to 70.0 mol %;
recurring units (IV): from 10.0 to 25.0 mol %, preferably from 15.0 to 22.0 mol %;
recurring units (V): from 10.0 to 25.0 mol %, preferably from 15.0 to 22.0 mol %.

More preferably pursuant to this embodiment (E2), the proportions are the following ones:
recurring units (I) or combination of recurring units (I) and recurring units (II) and/or (III): from 58 to 72 mol % or from 60 to 70 mol %;
recurring units (IV): from 15 to 22 mol %;
recurring units (V): from 15 to 22 mol %.

More preferably pursuant to this embodiment (E2), these proportions may also be the following ones:
recurring units (I) or combination of recurring units (I) and recurring units (II) and/or (III): from 58.0 to 72.0 mol % or from 60.0 to 70.0 mol %:
recurring units (IV): from 15.0 to 22.0 mol %;
recurring units (V): from 15.0 to 22.0 mol %.

Particularly, the polymer of the present disclosure preferably consists of:
from 30 mol % to 89 mol % of recurring units of formula (I),
from 1 mol % to 35 mol % of recurring units of formula (IV), and
from 10 mol % to 35 mol % of recurring units of formula (V),
the mol % being relative to the entire amount of moles of recurring units in the polymer.

Particularly, the polymer of the present disclosure yet more preferably consists of:
at least 30 mol %, or at least 50 mol %, or at least 55 mol %, or at least 60 mol %, of recurring units of formula (I) or of a combination of recurring units of formula (I) with recurring units of formula (II) and/or (III);
from 5 mol % to 35 mol %, or from 10 mol % to 25 mol %, or from 10 mol % to 20 mol %, or from 15 mol % to 20 mol %, of recurring units of formula (IVa); and
from 10 mol % to 35 mol %, or from 10 mol % to 25 mol %, or from 10 mol % to 20 mol %, of recurring units of formula (Va) and/or (Vb),
said mol % being relative to the entire amount of moles of recurring units in the polymer.

### Properties of the Polymer of the Invention

The melting temperature (Tm) of the polymer is usually at least 255° C. Tm is preferably at least 300° C., more preferably at least 350° C. In some embodiments, the Tm of the polymer is from 300° C. to 400° C., typically from 330° C. to 390° C.

A high Tm is beneficial in the field as the mobile device article or component needs to withstand the assembly processing steps typically found in the microelectronic manufacturing space. Various lamination/surface mount technologies (SMT) use high temperatures, typically above 260° C.

Tm is determined using differential scanning calorimetry (DSC) by methods and instrumentation known those of ordinary skill in the art. More particularly, Tm may be determined by DSC consists in subjecting the sample of the polymer in the powder form to a heat, cool and heat cycle at a heating and cooling rate of 20° C./min. Tₘ is determined using the maximum of the endothermic peak on the first heating cycle.

The method provided in the experimental section may more particularly be followed.

Tg of the polymer is usually at least 150° C. Tg is preferably higher than 160° C. Tg is typically lower than 200° C. Tg is typically between 160° C. and 180° C. Tg is determined using differential scanning calorimetry (DSC) by methods and instrumentation known those of ordinary skill in the art.

Tg is determined using differential scanning calorimetry (DSC) by methods and instrumentation known those of ordinary skill in the art. More particularly, Tg may be determined by DSC consists in subjecting the sample of the polymer in the powder form to a heat, cool and heat cycle at a heating and cooling rate of 20° C./min. T_{g} is then determined as the inflection point of the transition in the second heating cycle.

The method provided in the experimental section may more particularly be followed.

The polymer can be characterized by its dielectric properties, particularly dielectric constant (Dk or ε) and dissipation factor (Df). The dielectric constant and dissipation factor may be determined using methods and instrumentation known to those of ordinary skill in the art. One suitable method for measuring dielectric constant and dissipation factor of the mobile device article or component is using a Split Cylinder Resonator (SCR) according to the method described in IPC-TM-650 2.5.5.13. The method of measurement of the dielectric properties given in the experimental section may more particularly be followed.

In an embodiment, the polymer has:
a dielectric constant ε (Dk) at 20 GHz equal to or less than 3.6, and/or
a dissipation factor (Df) at 20 GHz of less than 0.0032, preferably less than 0.0020, wherein the Dk and Df of the polymer are measured according to IPC-TM-650 2.5.5.13 when the measurement is made in dry form, that is to say, on films of polymer immediately after drying in an oven at 100° C. for 1 hour.

In another embodiment, the mobile device article or component has:
a dielectric constant ε at 20 GHz equal to or of less than 3.6, and/or
a dissipation factor (Df) at 20 GHz of less than 0.0032, preferably less than 0.0030, wherein the Dk and Df of the mobile device article or component of the polymer are measured according to IPC-TM-650 2.5.5.13, when the measurement is made in wet form, that is to say, after soaking a film of the polymer in water at room temperature for 24 hours.

The mobile device article or component may exhibit the same values of Dk and Df.

### Preparation of the Polymer of the Invention

The polymer of the present disclosure is prepared by polycondensation. The polycondensation involves the use of the following monomers or acetylated monomers derived therefrom:
hydroxynaphtoic acid (HNA) (to obtain recurring units (I)) either alone or in combination with one or more hydroxy-benzoic acid;
the monomer of formula (IVb),

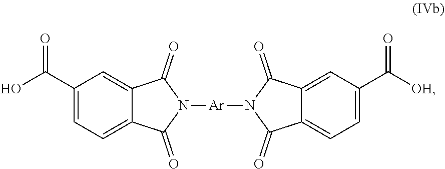

wherein Ar is as defined hereinabove;
one or more diol(s) of formula HO—Ar₁—OH, wherein Ar₁ is as defined hereinabove.

Recurring units (I) are derived from 6-acetoxy-2-naphthoic (HNA). Recurring units of formula (II) or (III), when present in the polymer according to the invention, are derived from hydroxy-benzoic acid monomers (respectively from 4-hydroxybenzoic acid (4-HBA) and from 3-hydroxybenzoic acid (3-HBA)).

The monomer of formula (IVb) may be obtained from commercial sources or synthesized according to methods known to those of ordinary skill in the art. For example, trimellitic anhydride may be reacted with a diamine having the formula H₂N—Ar—NH₂, in which Ar is as defined hereinabove. In an embodiment, the diamine is 2,2′-bis(trifluoromethyl)benzidine. The recipe provided in the experimental section may be followed for the preparation of the monomer of formula (IVb).

The monomer of formula (IVb) may be preferably a monomer of formula (IVc):

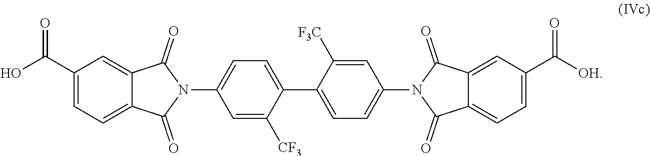 [SMILES: O=C(O)c1ccc2c(c1)C(=O)N(c1ccc(-c3ccc(N4C(=O)c5ccc(C(=O)O)cc5C4=O)cc3C(F)(F)F)c(C(F)(F)F)c1)C2=O]

Recurring units of formula (V) are derived from diols of formula HO—Ar₁—OH, wherein Ar₁ is as defined hereinabove. Exemplary diols include, but are not limited to, hydroquinone, resorcinol, 4,4′-biphenol, 3,3′-biphenol, 2,4′-biphenol, 2,3′-biphenol, 3,4′-biphenol, isomers of dihydroxynaphthalene, such as 1,4-dihydroxynaphthalene, 1,5-dihydroxynaphthalene, 2,3-dihydroxynaphthalene, 2,7-dihydroxynaphthalene, and 2,6-dihydroxynaphthalene; isomers of dihydroxyanthracene, such as 2,6-dihydroxyanthracene and 9,10-dihydroxyanthracene; and isomers of dihydroxyphenanthrene, such as 9,10-dihydroxyanthracene and 1,9-dihydroxyanthracene.

Recurring units of formula (VI), when present in the polymer according to the invention, are derived from diacids of formula HOOC—Ar₂—COOH, wherein Ar₂ is a defined hereinabove. Exemplary diacids include, but are not limited to, terephthalic acid, isophthalic acid, 2,6-naphthalic dicarboxylic acid, 3,6-naphthalic dicarboxylic acid, 1,5-naphthalic dicarboxylic acid, and 2,5-naphthalic dicarboxylic acid.

Recurring units of formula (VII), when present in the polymer according to the invention, are derived from hydroxycarboxylic acid monomers of formula HO—Ar₃—COOH, wherein Ar₃ is as defined hereinabove, that are different from HNA, 4-HBA, and 3-HBA.

The monomers bearing a reactive —OH group may be acetylated (either before or during polycondensation). Thus, the polycondensation may involve 6-acetoxy-2-naphthoic acid as a monomer to obtain the recurring units (I). Likewise, the diols may be acetylated (either before or during the polycondensation). Examples of acetylated diols are 1,3-phenylene diacetate (acetylated resorcinol) and/or 4,4′-diacetoxybiphenyl (acetylated 4,4′-biphenol). Thus, in one suitable method, the polymer is prepared by “pre-acetylation” in which these monomers are acetylated and isolated followed by introduction of the acetylated monomers into the polycondensation reactor in which the polycondensation is conducted. In another suitable method, the polymer is prepared by “in situ acetylation” in which these monomers are acetylated in the polycondensation reactor and the subsequent polycondensation phase is carried out in the same reactor.

The polycondensation is usually performed at a temperature which is at least 200° C. According to an embodiment, this temperature is increased step wise. An example of increase of the temperature at which the polycondensation is performed is provided in the experimental section. At the end of the polycondensation, the polymer can be recovered and dried.

The polymer of the invention may be prepared according to the recipe provided in the experimental section.

### Polymer Composition

In a second aspect, the present disclosure relates to a polymer composition comprising at least one polymer of the invention and optionally at least one additive selected in the group consisting of fillers (including reinforcing agents), tougheners, impact modifiers, plasticizers, colorants (e.g., pigments and/or dyes), surfactants, antistatic agents, lubricants, thermal stabilizers, light stabilizers, flame retardants, anti-drip agents, nucleating agents, chain-extenders, capping agents, laser light-activatable compounds, thermally conductive fillers, dielectric modifiers, and antioxidants.

The proportion of the additive(s) present in the polymer composition may be:
no more than 20 wt. %, no more than 15 wt. %, no more than 10 wt. %, no more than 7 wt. %, no more than 6 wt. %, no more than 5 wt. %, no more 3 wt. %, no more 2 wt. %, or no more 1 wt. %, based on the total weight of the polymer composition, and/or
at least 0.05 wt. %, at least 0.1 wt. %, at least 0.2 wt. %, at least 0.3 wt. %, at least 0.4 wt. %, at least 0.5 wt. %, at least 0.6 wt. %, at least 0.7 wt. %, or at least 0.8 wt. %, based on the total weight of the polymer composition.

The additive(s) is/are usually blended with the at least one polymer of the invention to form the polymer composition. Blending may be achieved conveniently through melt mixing the polymer(s) and the additive(s), e.g. with the aid of an extruder. Blending may also be achieved by mixing the polymer(s) and the additive(s) in a solvent and evaporating the solvent.

Some details about the additives that may be present in the polymer composition are now provided.

### Fillers

The polymer composition may comprise at least one filler. The filler may generally be selected from mineral fillers (such as talc, mica, kaolin, calcium carbonate, calcium silicate, magnesium carbonate), boron nitride, zinc oxide, graphene, glass fibers, carbon fibers, synthetic polymeric fibers, aramid fibers, aluminum fibers, titanium fibers, magnesium fibers, boron carbide fibers, rock wool fibers, steel fibers and inosilicates (e.g., wollastonite).

The filler may be an electrically and non-electrically thermally conductive filler, such as boron nitride, zinc oxide, or graphene.

The proportion of filler(s) may be:
no more than 60 wt. %, no more than 55 wt. %, no more than 50 wt. %, or no more than 45 wt. %, based on the total weight of the polymer composition, and/or
at least 5 wt. %, at least 10 wt. %, at least 15 wt. %, at least 20 wt. %, or at least 25 wt. %, based on the total weight of the polymer composition.

Preferably the polymer composition does not contain more than 20 wt. % (based on the total weight of the polymer composition) of additive(s).

The filler (including reinforcing agent, also called reinforcing filler) may be selected from fibrous and particulate reinforcing agents. A fibrous reinforcing filler is considered herein to be a material having length, width and thickness, wherein the average length is significantly larger than both the width and thickness. Generally, such a material has an aspect ratio, defined as the average ratio between the length and the largest of the width and thickness of at least 5, at least 10, at least 20 or at least 50.

The filler may be, for example, a low dielectric constant fiber filler, hollow fillers, particulate fillers, and the like.

The filler may be selected in the group of low dielectric constant fillers exhibiting a dielectric constant, Dk, of less than 5.0 at a frequency of from 1 megahertz (MHz) to 1 gigahertz (GHz) and a dissipation factor, Df, of less than 0.002 at a frequency of from 1 MHz to 1 GHz. Low dielectric constant particulate fillers include, but are not limited to, polymer particles, such as PTFE particles, LCP particles, and the like.

The filler may be selected in the group of glass fibers, advantageously in the group of glass fibers exhibiting a Dk of less than 5.0 at a frequency of from 1 MHz to 1 GHz and a Df of less than 0.002 at a frequency of from 1 MHz to 1 GHz. Exemplary glass fibers include, but are not limited to, E-glass, S-glass, AR-glass, T-glass, D-glass, R-glass, or combinations thereof.

The shape and size of suitable glass fibers, such as low dielectric constant glass fibers, are not limited. The fibers may include milled or chopped glass fibers. They may be in the form of whiskers or flakes. They may also be short glass fiber or long glass fiber. The glass fibers may have a length of 4 mm (millimeter) or longer are referred as to long fibers, and fibers shorter than this are referred to as short fibers. The glass fibers, including the low dielectric constant glass fiber, may have a round, flat, or irregular cross-section. Glass fibers having non-round cross-sections may be used. Alternatively, the glass fiber may have circular cross-sections. The diameter of the glass fiber may, for example, be from 1 to 15 μm. More specifically, the diameter of the low dielectric constant glass fiber may for example be from 4 to 10 μm. Flat glass fibers may also be used, for example flat glass fibers from Nitto Boseki Co., LTD (CSG 3PA-830).

Suitable fillers may be surface-treated with a surface treatment agent containing a coupling agent to improve adhesion to the polymer base resin. Suitable coupling agents include, but are not limited to, silane-based coupling agents, titanate-based coupling agents or a mixture thereof. Applicable silane-based coupling agents include aminosilane, epoxysilane, amidesilane, azidesilane and acrylsilane. Organo metallic coupling agents, for example, titanium or zirconium-based organo metallic compounds, may also be used.

Hollow fillers may, for example, be hollow glass spheres, hollow glass fibers, or hollow ceramic spheres. Exemplary hollow glass spheres have a density of from 0.2 grams per cubic centimeter (g/cm³) to 0.6 g/cm³. Typically, suitable hollow glass spheres have a diameter of from 5 μm to 50 μm.

### Impact Modifiers

The polymer composition may comprise at least one impact modifier. Tougheners, also called impact modifiers, are generally low glass transition temperature (Tg) natural or synthetic polymers, with a Tg for example below room temperature, below 0° C. or even below −25° C. As a result of their low Tg, tougheners are typically elastomeric at room temperature.

Tougheners can be functionalized polymer backbones. For example, suitable tougheners may be siloxane-based. The polymer backbone of the toughener may also be selected from elastomeric backbones comprising polyethylenes and copolymers thereof, e.g. ethylene-butene; ethylene-octene; polypropylenes and copolymers thereof; polybutenes; polyisoprenes; ethylene-propylene-rubbers (EPR); ethylene-propylene-diene monomer rubbers (EPDM); ethylene-acrylate rubbers; butadiene-acrylonitrile rubbers, ethylene-acrylic acid (EAA), ethylene-vinylacetate (EVA); acrylonitrile-butadiene-styrene rubbers (ABS), block copolymers styrene ethylene butadiene styrene (SEBS); block copolymers styrene butadiene styrene (SBS); core-shell elastomers of methacrylate-butadiene-styrene (MBS) type, or mixtures thereof.

When the toughener is functionalized, the functionalization of the backbone can result from the copolymerization of monomers which include the functionalization or from the grafting of the polymer backbone with a further component.

Notable examples of functionalized tougheners are terpolymers of ethylene, acrylic ester and glycidyl methacrylate, copolymers of ethylene and butyl ester acrylate; copolymers of ethylene, butyl ester acrylate and glycidyl methacrylate; ethylene-maleic anhydride copolymers; EPR grafted with maleic anhydride; styrene copolymers grafted with maleic anhydride; SEBS copolymers grafted with maleic anhydride; styrene-acrylonitrile copolymers grafted with maleic anhydride; and ABS copolymers grafted with maleic anhydride.

### Colorants

The polymer composition may comprise at least one colorant. One or more colorants such as pigments and/or dyes can be particularly desirable additives in the polymer composition to make a white, black or colored mobile device article or component.

### Laser-Activatable Compound

The polymer composition may comprise at least one laser-activatable compound. The laser light-activatable compound may be for example a spinel crystalline filler. The spinel crystalline fillers may be represented, but not necessarily, by the general formula: AB2O4 where A, is a metal cation typically having a valence 2, and is selected from a group comprising cadmium, chromium, manganese, nickel, zinc, copper, cobalt, iron, magnesium, tin, titanium, and combinations of two or more of these, and where B is a metal cation typically having a valence of 3, and is selected from the group comprising chromium, iron, aluminum, nickel, manganese, tin, and combinations of two or more of these, and where O is primarily, if not in all cases, oxygen. Examples of suitable laser light-activatable compounds may be titanium dioxide, aluminum nitride or zirconium dioxide filler.

The polymer composition included may also comprise other conventional additives commonly used in the art, including plasticizers, colorants, pigments (e.g. black pigments such as carbon black and nigrosine), antistatic agents, dyes, lubricants (e.g. linear low density polyethylene, calcium or magnesium stearate or sodium montanate), thermal stabilizers, light stabilizers, flame retardants, nucleating agents, mold release agents and antioxidants. Exemplary mold release agents include, but are not limited to, metal stearate, stearyl stearate, pentaerythritol tetrastearate, beeswax, montan wax, paraffin wax, or the like, or combinations including at least one of the foregoing mold release agents.

### Solution of the Polymer or of the Polymer Composition

In the third aspect, the present disclosure relates to a solution comprising the polymer described herein or the polymer composition described herein and a solvent. It was surprisingly discovered that the polymers described herein are soluble in certain solvents. Thus, articles, such as films, may be made by solution processing using solutions of the polymers described herein.

Suitable solvents are polar organic solvents. In an embodiment, the solvent is selected in the group of polar organic solvents. The solvent may typically be selected from N-methyl-2-pyrrolidone (NMP), dimethylformamide (DMF), 1,3-dimethyl-2-imidazolidinone (DMI), N,N-dimethylpropyleneurea (DMPU), dimethylacetamide (DMAc), dimethyl sulfoxide (DMSO), tetrahydrofuran (THF), acetonitrile, dimethyl-2-methyl glutarate, methyl 5-(dimethylamino)-2-methyl-5-oxopentanoate, dimethyl glutarate, dimethyl succinate, dimethyl adipate, γ-butyrolactone, dihydrolevoglucosenone, phenol, substituted phenols, and mixtures thereof.

The proportion of the polymer in the solution is not particularly limited so long as it is soluble in the solvent. However, in an embodiment, the concentration of the polymer in the solution is from 0.1 to 20%, typically from 1 to 10%, more typically from 2 to 5%, by weight of the solution.

### Application of the Polymer of the Invention

In a fourth aspect, the present disclosure relates to a mobile device article or component comprising the polymer or the polymer composition as described herein. In an embodiment, the mobile device article or component is in the form of a film, for example, for use as dielectric insulating substrates in PCBs or FPCs.

The mobile device article or component may be produced according to any method known to those of ordinary skill in the art. Exemplary methods for manufacturing the mobile device article or component include, but are not limited, injection molding, extrusion, compression molding, thermoforming, such as sheet thermoforming, vacuum forming, pressure forming, trapped sheet forming, steam pressure forming; liquid resin casting, transfer molding, and additive manufacturing, such as 3D printing.

The polymer or the polymer composition may also be injection molded for structural components of microelectronics and smart devices, mobile electronic device, i.e., an electronic device that is intended to be conveniently transported and used in various locations. A mobile electronic device can include, but is not limited to, a mobile phone, a personal digital assistant (“PDA”), a laptop computer, a tablet computer, a wearable computing device (e.g., a smart watch, smart glasses and the like), a camera, a portable audio player, wireless audio devices, a portable radio, global position system receivers, and portable game consoles.

The mobile device article or component may, for example, comprise a radio antenna. Herein, radio antennas are antennas capable of sending and receiving electromagnetic signals at radio frequencies. Radio antennas include, for example, those suitable for cellular, WiFi, Bluetooth, and RFID communications, and the like. The mobile device article or component may also be an antenna housing.

In some embodiments, the mobile device article or component may be a mounting component with mounting holes or other fastening device, including but not limited to, a snap fit connector between itself and another component of the mobile electronic device, including but not limited to, a circuit board, a microphone, a speaker, a display, a battery, a cover, a housing, an electrical or electronic connector, a hinge, a radio antenna, a switch, or a switchpad. In some embodiments, the mobile electronic device can be at least a portion of an input device.

In some embodiments, the mobile device article or component is used in transportation, for example, automotive (e.g. smart car/intelligent car, such as those with 5G capabilities), aeronautics and drones.

In a fifth aspect, the present disclosure relates to a metal clad laminate (La). The metal clad laminate comprises a layer (L_{PC}) made of or comprising the polymer of or the polymer composition as described herein and a metallic foil (L_{M}) bonded onto one side of layer (L_{PC}).

The metal is usually copper or stainless steel. The metal is preferably copper.

The copper foil may be an annealed copper foil or an electrodeposited copper foil.

The metal clad laminate may be prepared by a method comprising the step of putting into contact a solution comprising the polymer or the polmyer composition onto the surface of or a part of the surface of the metallic foil (L_{M}).

In the sixth aspect, the present disclosure relates to the use of the solution described herein for the manufacture of a film or a mobile electronic device article or component, or for the manufacture of an automotive, aeronautics or drone article or component.

The solution of the present disclosure may be used to produce articles, such as films, by solution processing. The use of the solutions in creating varnishes and/or coatings, optionally containing additives, is also contemplated. Suitable additives may be those described hereinabove and selected from the group consisting of fillers (including reinforcing agents), tougheners, impact modifiers, plasticizers, colorants, surfactants, pigments, antistatic agents, dyes, lubricants, thermal stabilizers, light stabilizers, flame retardants, anti-drip agents, nucleating agents, chain-extenders, cross-linking agents, capping agents, laser light-activatable compounds, thermally conductive fillers, dielectric modifiers, and antioxidants. For instance, a low Df filler, such as a low Df particulate filler, can be dispersed in the solution.

A suitable use would include depositing a layer of the solution described herein by, for example, casting, spray coating, spin coating, gravure coating, curtain coating, dip coating, slot-die coating, ink jet printing, gravure printing, or screen printing, on a substrate and removing the solvent from the layer. Typically, the solvent is removed from the layer by allowing the solvent component of the layer to evaporate.

The substrate supported layer may be subjected to elevated temperature and/or reduced pressure to encourage evaporation of the solvent. The substrate may be rigid or flexible and may comprise, for example, a metal, a polymer, a glass, a paper, or a ceramic material. For instance, the substrate may be a thin copper foil with a surface roughness ranging from 2-15 μm, for example copper foil available from Advanced Copper Foil Inc.

The invention is further illustrated by the following non-limiting examples.

### EXPERIMENTAL SECTION

### Example 1. Synthesis of 2,2′-(2,2′-bis(trifluoromethyl)-[1,1′-biphenyl]-4,4′-diyl)bis(1,3-dioxoisoindoline-5-carboxylic acid) (“Im-C12 monomer”)

An oven-dried 2 L, 2-neck round bottom flask equipped with a Dean-Stark trap, reflux condenser, nitrogen inlet/outlet, and magnetic stir bar was charged with 2,2′-bis(trifluoromethyl)benzidine (52.07 g, 0.16 mol) and anhydrous NMP (342 mL, 12.9 wt. % solution in NMP). The 2,2′-bis(trifluoromethyl)benzidine was allowed to dissolve in NMP at room temperature. Once dissolved, trimellitic anhydride (62.47 g, 0.32 mol) was added to the reaction and allowed to stir at room temperature for 16 hours to yield a clear, mild yellow/brown solution. After 16 hours, toluene (60 mL) was added to the reaction mixture and the solution was heated to 165° C. The reaction was monitored by observing the water content in the Dean-Stark trap and by thin-layer chromatography (TLC). The reaction was determined complete after 5 hours at 165° C. The light yellow, homogenous solution was allowed to cool down to room temperature with continued N₂ flow. The product was precipitated by the addition of deionized water (600 mL) and allowed to stir for 30 minutes. The white precipitate was collected by vacuum filtration, transferred to a 2 L Erlenmeyer flask, and washed three times with DI water (1,000 mL per wash) by stirring for 30 minute at room temperature. The product was placed in a vacuum oven at 100° C., 30 mmHg absolute pressure for 48 hours to yield 120.22 g of the Im-C12 product as a white solid, with residual NMP remaining.

### Example 2. PEI Synthesis and Preparation of PEI Films

Several PEI polymers were synthesized by polycondensation of HNA, Im-C12, and one or more diols. The following procedure is specific to the synthesis of one of the polymers, Polymer A, but is a representative procedure for all of the polymers prepared. It would be understood by those of ordinary skill in the art that parameters such as hold times at various temperatures and the ultimate pressure in the reactor may vary.

The reactions were performed in a dried 100 mL round bottom flask as reactor equipped with an overhead stirrer, nitrogen inlet, and distillation neck attached to a receiving flask. The PEI polymers were prepared using pre-acetylated monomers which were introduced to the melt polymerization reactor (flask) in which the polycondensation was conducted. 11.7727 g (60 mol %) of 6-acetoxy-2-naphthoic acid (pre-acetylated HNA), 11.4044 g (20 mol %) of Im-C12, 1.6617 g (10 mol %) of 1,3-phenylene diacetate (pre-acetylated resorcinol), and 2.3061 g (10 mol %) 4,4′-diacetoxybiphenyl (pre-acetylated 4,4′-biphenol) were charged to the flask under N₂ flow. Subsequent degassing with vacuum and N₂ gas purging (3×) produced an oxygen-free environment. The flask was then placed under N₂ flow, visualized by bubbling through a mineral oil bubbler. The flask was then submerged into a bismuth:tin alloy bath (58:42 w/w ratio) pre-heated to 240° C. and held for 25 min to begin melting the monomers. The temperature was then raised to 245° C. and held for an additional 10 min. The temperature of the reaction mixture was then ramped to 270° C. at a rate of 1° C./min and held at 270° C. for 30 min, resulting in a fully molten reaction mixture. The temperature was then raised to 320° C. at a rate of 1° C./min and held for 10 min under N₂ flow. The N₂ flow to the reactor was stopped and slight vacuum (250-290 mmHg absolute pressure) was applied to promote removal of acetic acid condensate for 10 min followed by application of high vacuum, reaching 2.5 mmHg absolute pressure. The reaction was held under high vacuum until no noticeable condensate was seen leaving the reaction and the polymer sample solidified around the stir blade, typically 1.5-2 h. The sample was subsequently cooled under N₂ flow and retrieved from the stir blade.

TABLE 1

| | HNA (mol %) | Im-C12 (mol %) | |
|---|---|---|---|
| | (recurring units | (recurring units | Diol (mol %) |
| Polymer | (I)) | (IV)) | (recurring units (V)) |
| A | 60 | 20 | 10 - biphenol |
| | | | 10 - resorcinol |
| B | 60 | 20 | 20 - resorcinol |
| C | 60 | 20 | 20 - biphenol |
| D | 65 | 17.5 | 17.5 - biphenol |
| E | 70 | 15 | 15 - biphenol |

### Preparation of Films of PEIs

The films were prepared by compression molding. Compression molding utilized two stainless steel plates layered with Kapton films and an aluminum shim to control thickness (0.0015″). The sandwich was centered in the press and allowed to heat to temperature for 2 min without applied pressure. After the initial heating step pressure was applied by contacting the top platen to the sandwich for the following cycle: 2 tons applied force for 0.75 min, release, 2 tons of applied force for 0.75 min, release. The sandwich was immediately removed from the press and allowed to cool on the bench. The films of PEIs were then removed from the sandwich and placed in an inert N₂ oven and annealed at 300° C. for 16 h.

### Example 3. Thermal, Dielectric, and Solubility Properties of Inventive PEIs

The PEIs made according to Example 2 were evaluated for their thermal, dielectric, and solubility properties as follows.

### Method of Measurement of the Glass Transition Temperature (Tg) and Melting Temperature (Tm)

Differential scanning calorimetry (DSC) was used to measure thermal transitions. DSC
was performed on samples that had been cryogenically milled to a fine powder. A heat,
cool, heat cycle was employed utilizing a heating and cooling rate of 20° C./min. Glass
transition temperatures (T_{g}) were determined as the inflection point of the transition in
the second heating cycle. Melting temperatures (Tₘ) were determined using the
maximum of the endothermic peak on the first heating cycle.

DSC instrument used: TA Instruments Q20-2 DSC, calibrated using indium (MP=156.60° C.), and maintaining an N₂ gas flow of 50 mL/min.

### Method of Measurement of the Dielectric Properties (Dk and Df)

The microwave dielectric properties were measured according to IPC-TM-650 2.5.5.13
on films melt-pressed and having been annealed at 300° C. for 16 hours, using a split
cylinder resonator operating at 20 GHz. The dielectric properties were measured on the
films either immediately after drying in an oven at 100° C. for 1 h or after soaking in
water at room temperature for 24 h. Those conditions are also denoted ″dry″ and
″wet″, respectively.

Split cylinder resonator used: KEAD 20 GHz SCR operating at 20 GHz.

### Solubility Test Used

Solubility testing was carried out by placing 5 wt. % of cryogenically milled polymer powder into a vial and adding 95 wt. % of N-methyl-2-pyrrolidone (NMP). The sample was then heated to 150° C. for 6 h. For samples exhibiting small quantities of particulates, the solution was passed through a bed of celite. For samples exhibiting a large quantity of particulates, no filtration was performed. The samples were then cooled to room temperature overnight and assessed for particulates the following day.

Results are reported as follows: ++ no particulate upon heating for 6 h and after cooling, + some particulate upon heating, none after filtration and cooling, − some particulate upon heating and particulates present after filtration and cooling, −− no or minimal solubility demonstrated after heating. The thermal, dielectric, and solubility properties of the inventive PEI polymers are summarized in Table 2 below.

TABLE 2

| | Tg | Tm | CLTE | Yield | Dk | Df | |
|---|---|---|---|---|---|---|---|
| Polymer | (° C.) | (° C.) | (ppm/° C.) | (° C.) | (dry) | (dry) | Solubility |
| A | 172.7 | 383 | 56 | 156 | 3.3 | 0.0014 | ++ |
| B | 169.6 | − | 98 | 162 | 3.2 | 0.0016 | ++ |
| C | 167.3 | 340 | 46 | 155 | 3.4 | 0.0015 | + |
| D | 171.2 | 339 | 70 | 161 | 3.6 | 0.0015 | + |
| E | 171.6 | 345 | 79 | 148 | 3.4 | 0.0011 | − − |

* Dk and Df measured on samples annealed at 300° C. for 16 h
** CLTE: Coefficient of Linear Thermal Expansion

As shown in Table 2, PEI polymers A-E display a unique combination of solubility and dielectric performance useful for various applications, such as articles or components in mobile electronic devices.

### Example 4. Effect of Humidity on the PEIs

The effect of humidity on the dielectric constant and dissipation factor of the PEIs was also evaluated. The dielectric properties were measured on films either immediately after drying in an oven at 100° C. for 0.5-1 h or after soaking in water at room temperature for 24 h, denoted “dry” and “wet”, respectively. The microwave dielectric properties were measured in accordance with IPC-TM-650 2.5.5.13 using a split cylinder resonator (KEAD 20 GHz SCR) operating at 20 GHz. For commercially available polyimide (PI) Cu-clad laminates (CCLs), the Cu layers were chemically etched away following the procedure laid out in IPC-TM-650 2.3.7. The results are summarized in Table 3 below.

TABLE 3

| Polymer | Dry Dk | Dry Df | Wet Dk | Wet Df | ΔDf |
|---|---|---|---|---|---|
| A | 3.3 | 0.0014 | 3.3 | 0.0026 | 0.0012 |
| B | 3.2 | 0.0016 | 3.2 | 0.0029 | 0.0013 |
| C | 3.4 | 0.0015 | 3.4 | 0.0020 | 0.0005 |
| D | 3.6 | 0.0015 | 3.6 | 0.0019 | 0.0004 |
| E | 3.4 | 0.0011 | 3.4 | 0.0015 | 0.0004 |
| Dupont Pyralux ® | 3.5 | 0.0042 | 3.6 | 0.0120 | 0.0078 |
| TA125012 (PI) | | | | | |
| UBE Upisel ®-N | 3.5 | 0.0045 | 3.6 | 0.0110 | 0.0065 |
| BE1210 (PI) | | | | | |

As shown in Table 3, the PEIs (Polymers A-E) did not exhibit significant increases in Df upon soaking in water for 24 hours as represented by the ΔDf (Df_{wet}−Df_{dry}) values of 0.0004 to 0.0013, compared to the commercially available PIs with ΔDf values of 0.0078 and 0.0065. The data in this table also demonstrate that the PEIs A-E provided an absolute Df value at 20 GHz that was better (much lower) than the commercially available PIs, even after equilibration in water.

1. A polymer comprising:
at least 30 mol % of recurring units of formula (I) or of a combination of a recurring units of formula (I) and recurring units selected from the group consisting of recurring units of formula (II), (III) and combination thereof: 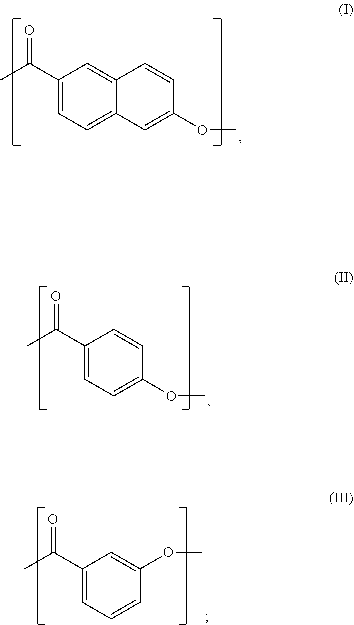
from 1 mol % to 35 mol % of recurring units of formula (IV): 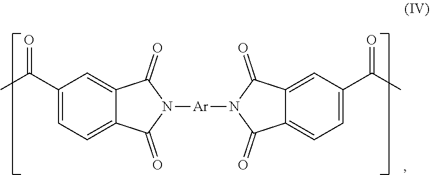
wherein Ar is selected from the group consisting of: 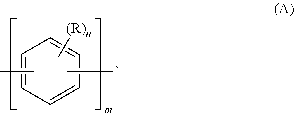
wherein
each occurrence of R is a C₃-C₈ spiro-substituted cycloaliphatic group, —NO₂, —CN, —OH, or a haloalkyl group,
m is an integer from 1 to 3, and
each occurrence of n is an integer from 0 to 4, with the proviso that at least one occurrence of n is an integer from 1 to 4; 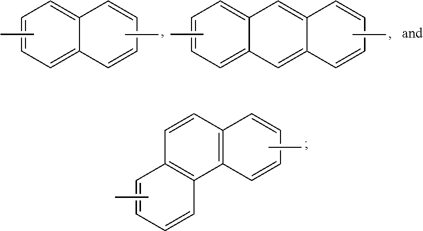
and
from 10 to 35 mol % of recurring units of formula (V):
[—O—Ar₁—O—] (V)
wherein Ar₁ is a C₆-C₁₈ arylene or —Ar_{c}-L₂-Ar_{d}—,
wherein Ar_{c} and Ar_{d} are each, independently, C₆-C₁₈ arylene, and L₂ is a divalent group selected from the group consisting of a bond, —O—, —S—, —SO—, SO₂—, —(C═O)—, —(C═O)O—, —(C═O)NH—, —(C═S)S—, —CH═CH—, —C(CH₃)₂—, and —C(CF₃)₂—;
said mol % being relative to the total amount of moles of recurring units in the polymer.

2. The polymer according to claim 1, wherein the proportion of recurring units (I) or of the combination of recurring units of formula (I) and recurring units selected from the group consisting of recurring units of formula (II), (III) and combination thereof is from 50 to 80 mol %.

3. (canceled)

4. The polymer according to claim 1, wherein the proportion of recurring units (IV) is from 5 to 35 mol %.

5. (canceled)

6. The polymer according to claim 1, wherein the proportion of recurring units (V) is from 10 to 25 mol %.

7. The polymer according to claim 1, comprising:
at least 30 mol % of recurring units of formulae (I);
from 1 mol % to 35 mol % of recurring units of formula (IV) and
from 10 mol % to 35 mol % of at least one recurring unit of formula (V),
said mol % being relative to the total amount of moles of recurring units in the polymer.

8. The polymer according to claim 1, with the following proportions:
recurring units (I) or combination of recurring units (I) and recurring units (II) and/or (III): from 55 to 75 mol %;
recurring units (IV): from 10 to 25 mol %;
recurring units (V): from 10 to 25 mol %.

9. (canceled)

10. The polymer according to claim 1, wherein Ar is represented by formula (A1):

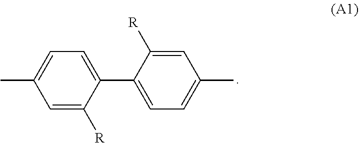

11. The polymer according to claim 1, wherein each occurrence of R in formula (A) or (A1) is selected from the group consisting of a C₃-C₈ spiro-substituted cycloaliphatic group, —NO₂, —CN, —OH and —(CHₚX_{q})ᵣCHₚX_{q′}, wherein each occurrence of X is a halogen atom, p and q are each an integer from 0 to 2, p′ and q′ are each an integer from 0 to 3, r is an integer from 0 to 20, satisfying the conditions that p+q=2, p′+q′=3 and q+q′ are equal to or greater than 1.

12. (canceled)

13. The polymer according to claim 10, wherein R is —CF₃.

14. The polymer according to claim 1, wherein the recurring units of formula (IV) are of formula (IVa):

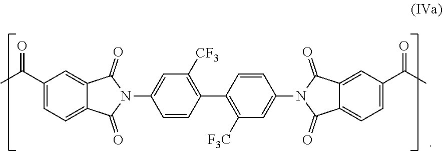

15. (canceled)

16. (canceled)

17. (canceled)

18. (canceled)

19. (canceled)

20. (canceled)

21. The polymer according to claim 1, further comprising recurring units of formula (VI), [—OC—Ar₂—CO—], wherein Ar₂ are each, independently, a C₆-C₁₈ arylene group.

22. The polymer according to claim 1, further comprising recurring units of formula (VII), [—O—Ar₃—CO—], wherein Ar₃ is a C₆-C₁₈ arylene group, different from recurring units of formulas (I), (II), and (III).

23. (canceled)

24. (canceled)

25. (canceled)

26. (canceled)

27. The polymer according to claim 1, exhibiting a melting temperature (Tm) of at least 255° C., Tm being determined by DSC wherein a sample of the polymer in the powder form is subjected to a heat, cool and heat cycle at a heating and cooling rate of 20° C./min and Tₘ is determined using the maximum of the endothermic peak on the first heating cycle.

28. (canceled)

29. The polymer according to claim 1, exhibiting a glass transition temperature (Tg) of at least 150° C. and lower than 200° C., Tg being determined by DSC wherein a sample of the polymer in the powder form is subjected to a heat, cool and heat cycle at a heating and cooling rate of 20° C./min and T_{g} is determined as the inflection point of the transition in the second heating cycle.

30. (canceled)

31. (canceled)

32. The polymer according to claim 1, exhibiting:
a dielectric constant F (Dk) at 20 GHz equal to or less than 3.6, and/or
a dissipation factor (Df) at 20 GHz of less than 0.0032,
wherein the Dk and Df are measured according to IPC-TM-650 2.5.5.13, the measurement being made on a film of polymer immediately after drying in an oven at 100° C. for 1 hour; and/or
a dielectric constant ε (Dk) at 20 GHz equal to or of less than 3.6, and/or
a dissipation factor (Df) at 20 GHz of less than 0.0032,
wherein the Dk and Df are measured according to IPC-TM-650 2.5.5.13, the measurement being made after soaking a film of the polymer in water at room temperature for 24 hours.

33. (canceled)

34. The polymer according to claim 1, exhibiting a ΔDf lower than 0.0015, where ΔDf is given by formula (Df_{wet}−Df_{dry}) where Df_{wet} and Df_{dry} are the Df values measured according to IPC-TM-650 2.5.5.13, the Df_{dry} being measured on a film of polymer immediately after drying in an oven at 100° C. for 1 hour and the Df_{wet} being measured on a film of the polymer after soaking in water at room temperature for 24 hours.

35. A polymer composition comprising at least one polymer according to claim 1 and at least one additive selected from the group consisting of fillers, tougheners, impact modifiers, plasticizers, colorants, surfactants, antistatic agents, lubricants, thermal stabilizers, light stabilizers, flame retardants, anti-drip agents, nucleating agents, chain-extenders, capping agents, laser light-activatable compounds, thermally conductive fillers, dielectric modifiers, and antioxidants.

36. (canceled)

37. (canceled)

38. (canceled)

39. (canceled)

40. A mobile device article or component comprising the polymer according to claim 1.

41. (canceled)

42. (canceled)

43. (canceled)

44. A solution comprising the polymer according to claim 1 and a solvent.

45. (canceled)

46. (canceled)

47. (canceled)

48. (canceled)

49. (canceled)

50. A metal clad laminate (Lₐ) comprising a layer (L_{PC}) comprising the polymer according to claim 1 and a metallic foil (L_{M}) bonded onto one side of the layer (L_{PC}).

51. (canceled)
